(19) United States
(12) Patent Application Publication
(10) Pub. No.: US 2012/0326304 A1
(43) Pub. Date: Dec. 27, 2012

(54) Externally Wire Bondable Chip Scale Package in a System-in-Package Module

(76) Inventors: Robert W. Warren, Newport Beach, CA (US); Nic Rossi, Radio City (HK)

(21) Appl. No.: 13/168,605

(22) Filed: Jun. 24, 2011

(51) Int. Cl. H01L 25/11; H01L 21/56; H01L 21/60

(52) U.S. Cl. 257/738; 438/107; 438/109; 257/E21.504; 257/E21.506; 257/E25.027; 257/E25.026

(57) ABSTRACT

There is provided a system and method for an externally wire bondable chip scale package in a system-in-package module. There is provided a system-in-package module comprising a substrate including a first contact pad disposed thereon, a packaged device attached to the substrate, wherein an electrode of the packaged device is wirebonded to the first contact pad, and an unpackaged device, wherein an electrode of the unpackaged device is coupled to the substrate. By flipping the packaged device within the module and utilizing wire bondable finishes on the packaged device, an externally wire bondable chip scale package may be provided. The structure of the disclosed system-in-package module provides several advantages over conventional designs including increased yields, a single assembly line, facilitated die substitution, reduced heat stress, higher package density, and a simplified single package structure for reduced fabrication time and cost.

### BACKGROUND OF THE INVENTION

1. Field of the Invention

The present invention relates generally to semiconductor devices. More particularly, the present invention relates to packaging of semiconductor devices.

2. Background Art

System-in-chip or multi-chip package modules are often desirable in many circuit applications due to increased functionality, high performance, and compact form factor. When the semiconductor devices or integrated circuits (ICs) to be packaged are readily available as bare die, it is relatively straightforward to fabricate a single integrated system-in-chip or multi-chip package using existing techniques.

However, certain types of semiconductor devices are difficult to procure as bare unpackaged die. For example, memory chips may undergo a fabrication process where faulty die yields are discarded and only known working devices are embedded into individual packages before distribution. In another example, sensitive devices such as micro-electro-mechanical systems (MEMS) may only be available in packaged form for protection against environmental conditions and handling. Furthermore, pre-assembled packaged devices that are pre-tested and known to work may be preferable in certain applications. Thus, it may be desirable to fabricate a single system-in-chip or multi-chip package integrating such packaged devices with other devices in bare die form, such as logic ICs.

Unfortunately, the packaged form factor of such packaged devices limits available design options for efficient integration with unpackaged devices. One approach is to place the packaged and unpackaged devices dies side-by-side on a shared package substrate. Conventionally, such a shared package is manufactured by soldering packaged devices to the substrate using one assembly line, and then by wirebonding any unpackaged devices to the substrate using a clean-room microelectronic assembly line. However, the requirement of two separate assembly lines using different equipment and processes undesirably increases manufacturing costs and complexity.

Another approach is to place the unpackaged device into its own package and then stack the individual packages to form a composite module. However, by requiring at least two stacked packages rather than a single integrated package, this approach reduces thermal and electrical performance while increasing height, manufacturing cost and complexity.

Accordingly, there is a need to overcome the drawbacks and deficiencies in the art by providing a way to efficiently integrate packaged and unpackaged devices in a single package.

### SUMMARY OF THE INVENTION

There are provided systems and methods for an externally wire bondable chip scale package in a system-in-package module, substantially as shown in and/or described in connection with at least one of the figures, as set forth more completely in the claims.

### BRIEF DESCRIPTION OF THE DRAWINGS

The features and advantages of the present invention will become more readily apparent to those ordinarily skilled in the art after reviewing the following detailed description and accompanying drawings, wherein:

FIG. 1A presents a bottom view of a conventional packaged device;

FIG. 1B presents a cross sectional view of a conventional packaged device;

FIG. 1C presents a cross sectional view of a conventional package-in-package module for integrating a packaged device and an unpackaged device;

FIG. 1D presents a cross sectional view of a conventional package-on-package module for integrating a packaged device and an unpackaged device;

FIG. 2A presents a cross sectional view of an exemplary system-in-package module for an externally wire bondable chip scale package with an unpackaged device, according to an embodiment of the present invention;

FIG. 2B presents a cross sectional view of an exemplary system-in-package module for an externally wire bondable chip scale package stacked with an unpackaged device, according to an embodiment of the present invention;

FIG. 3 shows a flowchart describing the steps, according to one embodiment of the present invention, by which a system-in-package module for an externally wire bondable chip scale package with an unpackaged device may be provided.

### DETAILED DESCRIPTION OF THE INVENTION

The present application is directed to a system and method for an externally wire bondable chip scale package in a system-in-package module. The following description contains specific information pertaining to the implementation of the present invention. One skilled in the art will recognize that the present invention may be implemented in a manner different from that specifically discussed in the present application. Moreover, some of the specific details of the invention are not discussed in order not to obscure the invention. The specific details not described in the present application are within the knowledge of a person of ordinary skill in the art. The drawings in the present application and their accompanying detailed description are directed to merely exemplary embodiments of the invention. To maintain brevity, other embodiments of the invention, which use the principles of the present invention, are not specifically described in the present application and are not specifically illustrated by the present drawings. Additionally, for reasons of clarity, the drawings may not be to scale.

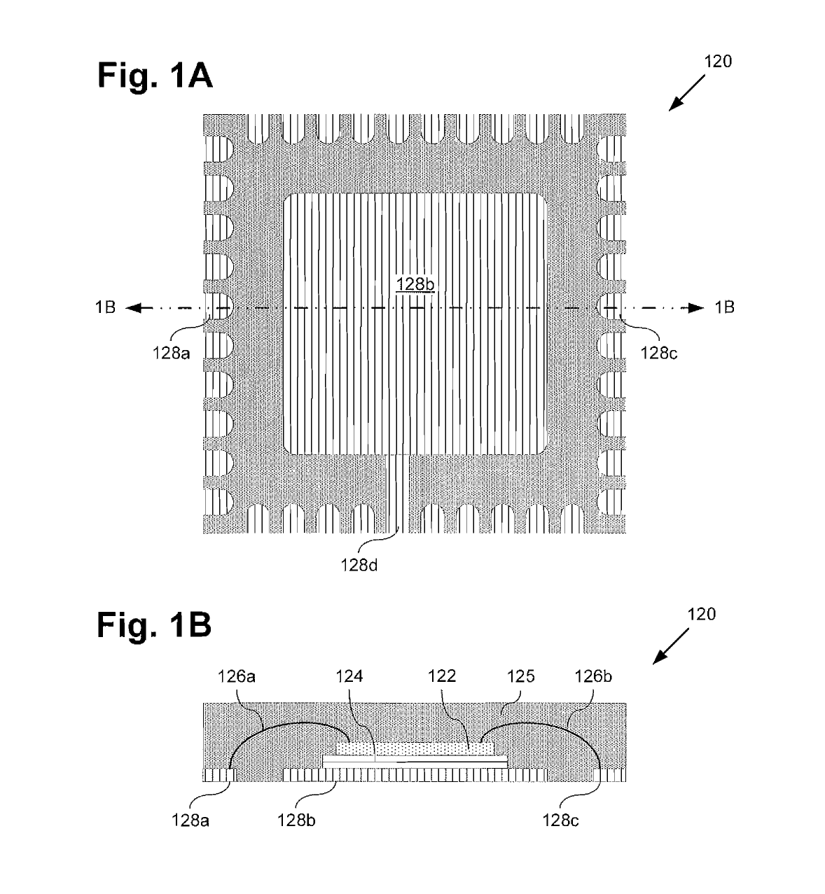

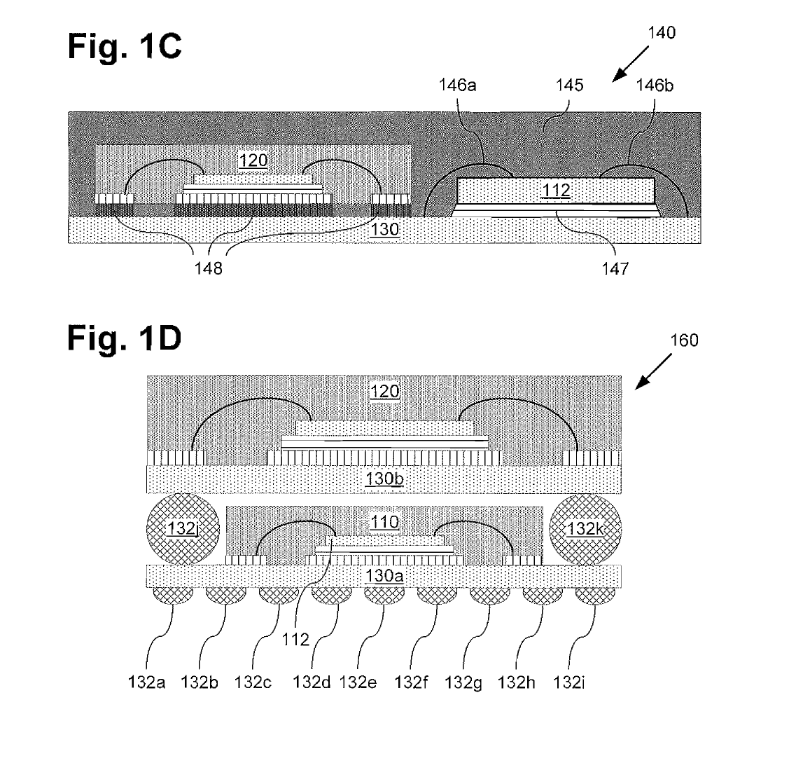

FIG. 1A presents a bottom view of a conventional packaged device. Packaged device 120 may comprise, for example, a packaged memory chip, a MEMS device, or another device that is more readily available in a pre-packaged form or a device preferred in a pre-packaged form to ensure tested and known good die. Packaged device 120 may comprise a chip scale package in a quad flat no leads (QFN) package configuration. As shown in FIG. 1A, package terminals 128a, 128b, 128c, and 128d are exposed at the bottom of package 120, and package terminal 128b may be optionally fused to package terminal 128d to provide a die paddle connection. The bottom side package electrodes including package terminals 128a, 128b, 128c and 128d may be directly solderable to a support surface. Although a single row QFN is shown in FIG. 1A, alternative embodiments may utilize other chip scale packages such as dual row QFN, array QFN, build-up array QFN, land grid array (LGA), and others. Alternatively, cavity packages such as hermetic or near-hermetic packages may be utilized.

FIG. 1B presents a cross sectional view of a conventional packaged device. The portion shown in FIG. 1B corresponds to the cross sectional line indicated by line 1B-1B of FIG. 1A. Packaged device 120 includes semiconductor device die 122, adhesive 124, wirebonds 126a and 126b, and package terminals 128a, 128b, and 128c. Semiconductor device die 122 may comprise, for example, a memory chip IC. Adhesive 124 may comprise, for example, an electrically and/or thermally conductive or non-conductive epoxy. Wirebonds 126a and 126b may comprise conventional gold, copper, or aluminum wirebonds or other attachment means such as metallic clips or ribbons. While FIG. 1B shows package terminals exclusively on a bottom surface of packaged device 120, alternative embodiments may also include package terminals on a top surface of packaged device 120.

As previously discussed above, it may be desirable to integrate packaged device 120 with other bare dies. To this end, various conventional approaches have been attempted, but each approach has shown several drawbacks. One such conventional approach is shown in FIG. 1C. FIG. 1C presents a cross sectional view of a conventional package-in-package module for integrating a packaged device and an unpackaged device. Package 140 of FIG. 1C includes packaged device 120 and unpackaged device 112 placed side-by-side on substrate 130 and encapsulated in mold compound 145. Unpackaged device 112 may comprise, for example, a bare semiconductor device die such as a logic IC, whereas packaged device 120 may correspond to packaged device 120 from FIGS. 1A and 1B. Packaged device 120 may be soldered directly to substrate 130 with solder alloy 148, as is known in the art. Unpackaged device 112 may be attached and connected to substrate 130 using die attach epoxy adhesive 147 and wirebonds 146a and 146b. In turn, traces within substrate 130, omitted from FIG. 1C, may electrically couple the connections of packaged device 120 and unpackaged device 112 as necessary to complete the desired circuit. Alternatively, traces in the receiving support board may provide the necessary connections. However, as previously described, the process of attaching packaged device 120 requires one assembly line for soldering, whereas the process of attaching unpackaged device 112 requires a different assembly line for die attach and wirebonding, disadvantageously increasing manufacturing complexity and cost.

Another conventional approach is shown in FIG. 1D. FIG. 1D presents a cross sectional view of a conventional package-on-package module for integrating a packaged device and an unpackaged device. Module 160 of FIG. 1D includes package 110, package 120, and solder balls 132a, 132b, 132c, 132d, 132e, 132f, 132g, 132h, 132i, 132j, and 132k. The structure of package 110 may correspond to the structure of packaged device 120 from FIGS. 1A and 1B. Package 110 includes semiconductor device die 112, which may correspond to unpackaged device 112 from FIG. 1C. Package 120 may correspond to packaged device 120 from FIGS. 1A and 1B. Package 110 and 120 are each mounted on a respective substrate 130a and 130b. Substrate 130a and 130b may each correspond to substrate 130 from FIG. 1C, and may more specifically comprise BGA substrates, with substrate 130a having solder balls 132a-132i attached and substrate 130b having solder balls 132j and 132k attached. In this manner, the unpackaged device 112 and the packaged device 120 from FIG. 1A may be integrated as a composite module. However, as seen in FIG. 1D, the height of module 160 is disadvantageously increased, the semiconductor device die 112 must be placed in its own package 110, and the complexity and cost is greatly increased compared to a single unified package.

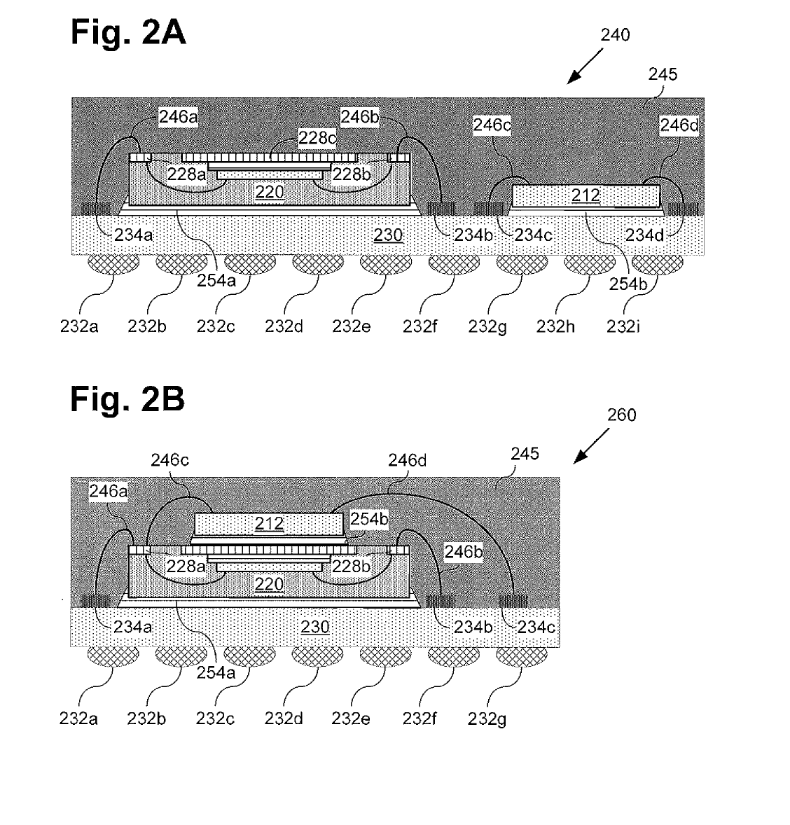

Thus, to avoid the problems associated with the above conventional designs, a novel system-in-package module including an externally wire bondable chip scale package is disclosed below. Starting with FIG. 2A, FIG. 2A presents a cross sectional view of an exemplary system-in-package module for an externally wire bondable chip scale package with an unpackaged device, according to an embodiment of the present invention. Module 240 of FIG. 2A includes substrate 230, contact pads 234a, 234b, 234c and 234d, unpackaged device 212, packaged device 220, adhesive 254a and 254b, wirebonds 246a, 246b, 246c and 246d, solder bumps 232a, 232b, 232c, 232d, 232e, 232f, 232g, 232h, and 232i, and mold compound 245. Substrate 230 may specifically comprise a BGA substrate, but in alternative embodiments substrate 230 may comprise any type of substrate such as a silicon substrate, a ceramic substrate, a direct bonded copper (DBC) substrate, copper leadframe, or another type of substrate. Contact pads 234a through 234d may each comprise wirebondable surface finish materials such as nickel-palladium-gold (NiPdAu), nickel-gold (NiAu), palladium (Pd), silver (Ag), and direct gold over copper (AuCu). Adhesive 254a and 254b may comprise electrically and/or conductive or non-conductive adhesive materials such as epoxy. Wirebonds 246a through 246d may comprise gold, copper, or aluminum wirebonds or other attachment means such as metallic clips or ribbons.

With respect to FIG. 2A, packaged device 220 may correspond to packaged device 120 from FIGS. 1A and 1B, and unpackaged device 212 may correspond to unpackaged device 112 from FIG. 1C. Additionally, while the cross sectional area shown in FIG. 2A is only large enough to accommodate a single system-in-package module, it is to be understood that substrate 230 may comprise part of a larger wafer accommodating multiple system-in-package modules that are later singulated into individual devices.

As shown in FIG. 2A, both packaged device 220 and unpackaged device 212 may be attached to substrate 230 using adhesive 254a and 254b, respectively. Furthermore, both packaged device 220 and unpackaged device 212 are attached to substrate 230 using wirebonds, or wirebonds 246a through 246d. Accordingly, module 240 may be advantageously fabricated using a single assembly line for wirebonding. In contrast, module 140 of FIG. 1C requires two separate assembly lines for soldering and wirebonding, increasing manufacturing cost and complexity.

The structure of module 240 is enabled by recent trends in package surface finishes. Due to a variety of factors including cost, compliance with the Restriction of Hazardous Substances directive (RoHS), coplanarity, and test contact and tin (Sn) whisker reliability issues, package finishes have been transitioning away from traditional tin and matte tin and similar solder alloys to alternative lead-free materials that are low cost, have a flat and uniform contact surface, are free of dendritic whiskering, and are both solderable and wirebondable. Of particular interest are finishes such as electro-less nickel, electro-less palladium, immersion gold (Ni/Pd/Au) and electro-less nickel, electro-less palladium, immersion gold-silver (Ni/Pd/Au—Ag) for QFN lead frames, and finishes such as electro-less nickel, electro-less gold (Ni/Au) or electro-lytic nickel, electro-lytic gold (Ni/Au), or electro-less nickel, immersion gold (Ni/Au) for LGAs or ceramic packages, to provide a few examples. Besides providing highly uniform height and being lead-free, these finishes have also shown to demonstrate high wirebonding strength, thereby providing a versatile finish that can be either directly soldered to a support surface or wirebonded.

Thus, the electrodes of packaged device 220 may be plated with one of the above listed finishes, providing readily wire bondable surface finishes for package terminals 228a, 228b, and 228c. Packaged device 220 may comprise a chip scale surface mount device normally intended for direct soldering to a support surface. However, since package terminals 228a, 228b, and 228c may be coated with a wire bondable finish, the packaged device 220 may be flipped over to expose the package terminals 228a, 228b, and 228c for external wirebonding. Thus, wirebond 246a may be attached to package terminal 228a and contact pad 234a, and wirebond 246b may be attached to package terminal 228b and contact pad 234b. Additionally, wirebonds 246c and 246d may connect terminals of unpackaged device 212 to contact pads 234c and 234d, respectively.

Traces within substrate 230 or in a receiving support surface may then complete the necessary connections between unpackaged device 212, package 220, and any other included devices to connect the desired system-in-package circuit. Module 240 may also be encapsulated in mold compound 245, but in alternative embodiments module 240 may instead be hermetically sealed. Additionally, as shown in FIG. 2A, substrate 230 may specifically comprise a BGA substrate with solder bumps 232a, 232b, 232c, 232d, 232e, 232f, 232g, 232h, and 232i attached to the bottom of substrate 230.

Moving to FIG. 2B, FIG. 2B presents a cross sectional view of an exemplary system-in-package module for an externally wire bondable chip scale package stacked with an unpackaged device, according to an embodiment of the present invention. Module 260 of FIG. 2B may be constructed in a manner similar to that of module 240 in FIG. 2A. However, comparing FIG. 2A with FIG. 2B, it can be seen that in module 260 of FIG. 2B, unpackaged device 212 is stacked on top of packaged device 220 rather than placed side-by-side with packaged device 220. This arrangement may be desirable to reduce the lateral size of module 260 compared to module 240. Additionally, interconnections may be made by combining multiple wirebonds on a single terminal instead of using traces in substrate 230. For example, wirebond 246a and wirebond 246c are both connected to package terminal 228a, providing an interconnection between an electrode of packaged device 220 and an electrode of unpackaged device 212. Additionally, for alternative embodiments providing larger multi-chip modules, the side-by-side approach shown in FIG. 2A and the stacking approach shown in FIG. 2B may be combined.

The disclosed system-in-package modules provide several advantages. First, because both the unpackaged device 212 and the packaged device 220 may be attached using adhesive epoxy and wirebonded to connect respective package terminals or electrodes, only a single wirebonding assembly line is required. Second, because packaged device 220 may be known as a tested working device, the assembly and final yields for the modules may be improved. Third, because the form factor of the modules may remain constant, die shrinks or substitutions of unpackaged device 212 may be easily accommodated without changing board design layouts. Fourth, because of the trend towards highly wire bondable package finishes, gold wire bonds suitable for sensitive devices may be utilized for packaged device 220, whereas lower cost copper wire bonds may be used elsewhere in the modules. Fifth, because a high temperature soldering step may be avoided by using the single wirebonding assembly line, heat sensitive packages such as MEMS devices can be more reliably integrated into the modules, larger modules may be built without warping effects from high temperatures, and higher packaging density may be achieved by safely disregarding keep-out distance from solder pads to wirebond pads. Sixth, because the unpackaged device 212 may be stacked on top of packaged device 220, lateral size may be reduced and device interconnections are made possible by using multiple wirebonds on single terminals of packaged device 220. Seventh, because the modules are fabricated as a single integrated package, assembly is simplified and only a single metal finish is necessary for the contact pads, reducing fabrication time and costs while improving device performance and optimizing form factor. Thus, it can be seen that the disclosed system-in-package module including an externally wire bondable chip scale package provides numerous advantages over conventional designs for integrating unpackaged and packaged IC.

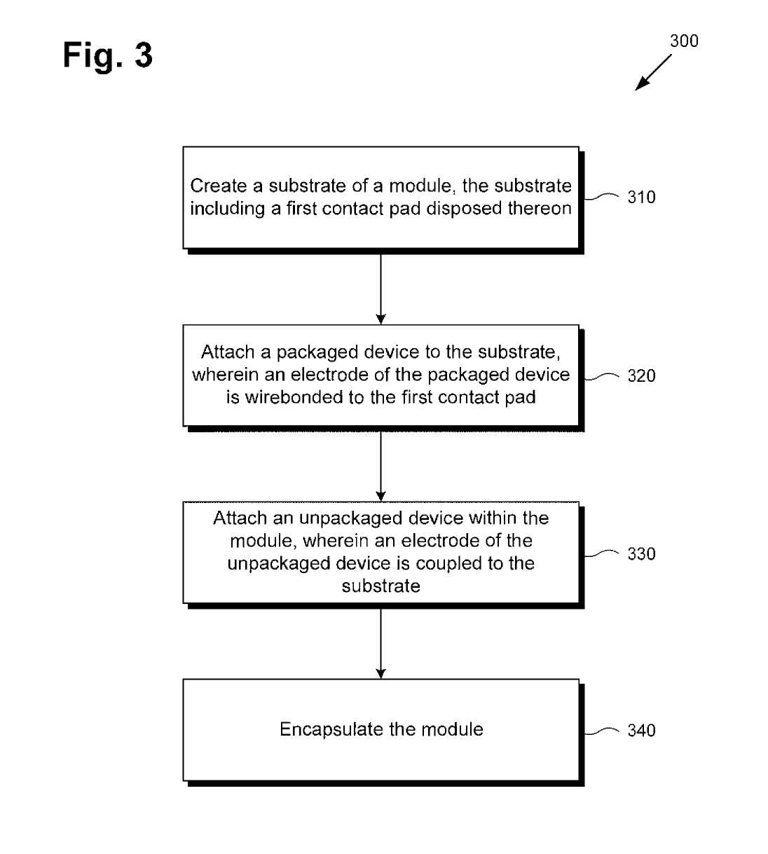

FIG. 3 shows a flowchart describing the steps, according to one embodiment of the present invention, by which a system-in-package module for an externally wire bondable chip scale package with an unpackaged device may be provided. Certain details and features have been left out of flowchart 300 that are apparent to a person of ordinary skill in the art. For example, a step may comprise one or more substeps or may involve specialized equipment or materials, as known in the art. While steps 310 through 340 indicated in flowchart 300 are sufficient to describe one embodiment of the present invention, other embodiments of the invention may utilize steps different from those shown in flowchart 300.

Referring to step 310 of flowchart 300 in FIG. 3 and module 240 of FIG. 2A, step 310 of flowchart 300 comprises creating substrate 230 of module 240, substrate 230 including a first contact pad, or contact pad 234a, disposed thereon. As previously discussed, substrate 230 may comprise any number of different substrate types, but for the present example it may be assumed that substrate 230 is a BGA substrate including solder bumps 232a through 232i. Additionally, contact pads 234b, 234c, and 234d are also formed. Contact pads 234a through 234d may all be formed using a single metal finish and may comprise an easily solderable tri-metal such as NiPdAu, as previously described.

Referring to step 320 of flowchart 300 in FIG. 3 and module 240 of FIG. 2A, step 320 of flowchart 300 comprises attaching packaged device 220 to substrate 230, wherein an electrode or terminal 228a of packaged device 220 is wirebonded to contact pad 234a. Thus, packaged device 220 is attached to substrate 230 by adhesive 254a, comprising an electrically and/or thermally conductive or non-conductive epoxy. Terminal 228a is also wirebonded to contact pad 234a using wirebond 246a, which may comprise a gold, copper, or aluminum wirebond or another attachment means such as a metallic clip or ribbon. As previously discussed, packaged device 220 may include various finishes on package terminals 228a, 228b, and 228c that are especially amenable to wire bonding, including Ni/Pd/Au, Ni/Pd/Au—Ag, and Ni/Au with electro-less or electro-lytic gold.

Referring to step 330 of flowchart 300 in FIG. 3 and module 240 of FIG. 2A, step 330 of flowchart 300 comprises attaching unpackaged device 212 within module 240, wherein an electrode of unpackaged device 212 is coupled to substrate 230. Similar to step 320, unpackaged device 212 is attached to substrate 230 by adhesive 254b, and wirebond 246c couples the electrode of unpackaged device 212 to a second contact pad, or contact pad 234c, which in turn is coupled to substrate 230. Thus, unpackaged device 212 is placed side-by-side with packaged device 220. However, in alternative embodiments, unpackaged device 212 may be stacked atop of packaged device 220, as in module 260 of FIG. 2B. In this case, the electrode of unpackaged device 212 may couple to substrate 230 by wirebond 246c, which connects to package terminal 228a, which in turn connects to contact pad 234a via wirebond 246a.

As previously discussed, both steps 320 and 330 may be advantageously carried out using a single wirebonding assembly line rather than using separate assembly lines for soldering and wirebonding, thereby reducing manufacturing cost and complexity while providing various advantages as described above.

Referring to step 340 of flowchart 300 in FIG. 3 and module 240 of FIG. 2A, step 340 of flowchart 300 comprises encapsulating module 240 with mold compound 245. However, in alternative embodiments, a hermetic seal may be used instead. After step 340, when module 240 is completed, it may be singulated from a larger wafer, as previously discussed. Thus, a method for providing a system-in-package module including an externally wire bondable chip scale package with an unpackaged device has been disclosed.

From the above description of the invention it is manifest that various techniques can be used for implementing the concepts of the present invention without departing from its scope. Moreover, while the invention has been described with specific reference to certain embodiments, a person of ordinary skills in the art would recognize that changes can be made in form and detail without departing from the spirit and the scope of the invention. As such, the described embodiments are to be considered in all respects as illustrative and not restrictive. It should also be understood that the invention is not limited to the particular embodiments described herein, but is capable of many rearrangements, modifications, and substitutions without departing from the scope of the invention.

What is claimed is:

1. A system-in-package module comprising:
a substrate including a first contact pad disposed thereon;
a packaged device attached to the substrate, wherein an electrode of the packaged device is wirebonded to the first contact pad;
an unpackaged device, wherein an electrode of the unpackaged device is coupled to the substrate.

2. The module of claim 1, wherein the unpackaged device is stacked atop the packaged device using an adhesive epoxy.

3. The module of claim 1, wherein the unpackaged device is attached to the substrate using an adhesive epoxy.

4. The module of claim 1, wherein the electrode of the unpackaged device is wirebonded to a second contact pad of the substrate.

5. The module of claim 1, wherein the electrode of the unpackaged device is wirebonded to the electrode of the packaged device.

6. The module of claim 1, wherein the packaged device includes an electroless nickel, electroless palladium, immersion gold finish on the electrode.

7. The module of claim 1, wherein the packaged device includes an electroless nickel, electroless gold finish on the electrode.

8. The module of claim 1, wherein the substrate is a ball grid array (BGA) substrate.

9. The module of claim 1, wherein the packaged device is attached to the substrate using an adhesive epoxy.

10. The module of claim 1, further comprising a mold compound encapsulating the module.

11. A method of fabricating a system-in-package module, the method comprising:
creating a substrate including a first contact pad disposed thereon;
attaching a packaged device to the substrate, wherein an electrode of the packaged device is wirebonded to the first contact pad;
attaching an unpackaged device within the module, wherein an electrode of the unpackaged device is coupled to the substrate.

12. The method of claim 11, wherein the attaching of the unpackaged device is by stacking atop the packaged device using an adhesive epoxy.

13. The method of claim 11, wherein the attaching of the unpackaged device is to the substrate using an adhesive epoxy.

14. The method of claim 11, wherein the electrode of the unpackaged device is wirebonded to a second contact pad of the substrate.

15. The method of claim 11, wherein the electrode of the unpackaged device is wirebonded to the electrode of the packaged device.

16. The method of claim 11, wherein the packaged device includes an electroless nickel, electroless palladium, immersion gold finish on the electrode.

17. The method of claim 11, wherein the packaged device includes an electroless nickel, electroless gold finish on the electrode.

18. The method of claim 11, wherein the substrate is a ball grid array (BGA) substrate.

19. The method of claim 11, wherein the attaching of the packaged device and the attaching of the unpackaged device uses a single assembly line.

20. The method of claim 11, further comprising encapsulating the module with a mold compound.
